(19) United States
(12) Patent Application Publication
(10) Pub. No.: US 2024/0280624 A1
(43) Pub. Date: Aug. 22, 2024

(54) METHODS OF FAULT DETECTION USING A PERIODIC SIGNAL

(71) Applicant: Microchip Technology Incorporated, Chandler, AZ (US)

(72) Inventors: Dixon Chen, Shenzhen (CN); Yanzi Xu, Shenzhen (CN); Henry Liang, Shenzhen (CN); Kevin Yang, Shenzhen (CN); Thor Lei Xia, Shenzhen (CN); Jiachi Yu, Foshan (CN)

(21) Appl. No.: 18/444,319

(22) Filed: Feb. 16, 2024

(30) Foreign Application Priority Data
Feb. 17, 2023 (CN) 202310177686.0

(51) Int. Cl. G01R 31/11; G01R 31/08

(52) U.S. Cl. CPC G01R 31/11; G01R 31/083

(57) ABSTRACT

An apparatus may comprise processing circuitry, a first pair of terminals, and a second pair of terminals that are electrically connected to a cable. The processing circuitry may provide a periodic signal including pulses to the first terminal. The duration of each of the pulses may be at least double the time of travel of the pulses along the length of the cable. The processing circuitry may also detect a fault in the cable responsive to a received signal at the second terminal responsive to the periodic signal.

### PRIORITY CLAIM

This application claims the benefit of the filing date of Chinese Patent Application Serial No. 202310177686.0, filed Feb. 17, 2023, for “IMPROVED METHODS OF FAULT DETECTION USING A PERIODIC SIGNAL.”

### TECHNICAL FIELD

Embodiments of the present disclosure relate generally to apparatuses and methods for fault detection using a periodic signal.

### BACKGROUND

Cables, such as network cables, function as electrical transmission lines that transmit power and/or information using electrical currents. If the conductor or insulation of a cable is damaged, a cable fault may occur. Two typical faults that occur in a cable include an open-circuit fault and a short-circuit fault. An open-circuit fault occurs when there is a break in the conductor of the cable, which prevents and/or attenuates transmission of electrical signals through the cable. A short-circuit fault typically occurs when two conductors of the cable come into contact with each other due to a failure of the insulation of the cable. Both open-circuit and short-circuit faults may degrade performance of a cable or render the cable useless. Because cables are used extensively in modern infrastructure, cable faults may create wide-spread problems for a multitude of industries. Moreover, cables are often laid underground, or are routed through complex objects such as vehicles, making fault identification and fault repair costly and time-intensive.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a functional block diagram of a network segment, according to one or more examples;

FIG. 2 illustrates a fault detection apparatus, according to one or more examples;

FIG. 3 is a flow chart illustrating a method of detecting a fault in a cable, according to one or more examples;

FIG. 4 is a flowchart illustrating a method of detecting and locating an open circuit fault in a cable, according to one or more examples;

FIG. 5 is a flowchart illustrating a method of detecting and locating a short circuit fault in a cable, according to one or more examples;

FIG. 6 is a flowchart illustrating a method of detecting a fault in a cable at a point of connection between the cable and a first terminal, according to one or more examples;

FIG. 7 is a flowchart illustrating a method of detecting a fault in a cable at a distance greater than substantially zero meters from a point of connection between the cable and a first terminal, according to one or more examples;

FIG. 8 is a flowchart illustrating a method of detecting a fault in a cable using a clock signal, according to one or more examples;

FIG. 9 is a flowchart illustrating a method of detecting and locating an open circuit fault in a cable using a clock signal, according to one or more examples;

FIG. 10 is a flowchart illustrating a method of detecting and locating a short circuit fault in a cable using a clock signal, according to one or more examples;

FIGS. 11A-11D represent signal timing diagrams according to one or more examples;

FIG. 12 is a block diagram of a fault detection system, according to one or more examples; and

FIG. 13 is a block diagram of circuitry that, in one or more examples, may be used to implement various functions, operations, acts, processes, and/or methods disclosed herein.

### DETAILED DESCRIPTION

In the following detailed description, reference is made to the accompanying drawings, which form a part hereof, and in which are shown, by way of illustration, specific examples of examples in which the present disclosure may be practiced. These examples are described in sufficient detail to enable a person of ordinary skill in the art to practice the present disclosure. However, other examples enabled herein may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. In some instances similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope of the present disclosure, but is merely representative of various examples. While the various aspects of the examples may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts may be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, the term “echo,” when used with reference to a signal, refers to the transmitted signal being looped back directly to the receive path. The transmitted signal is understood to be a differential signal, being transmitted on a pair of wires, respectively termed the positive and negative wires, and thus the receive and transmit wires may be the same, e.g., 10BASE-T1S as described in IEEE Std 802.3cg-2019, thereby defining the loop back. A short circuit is therefore a connection between the positive and negative wires.

As used herein, the phrase “maximum allowed length,” when used with reference to a transmission line such as a cable, refers to a maximum length of the transmission line allowed by standards governing the transmission line. For example, a standard governing cable fault detection may require that a cable that is being tested by a fault detection system be no longer than a maximum allowed length. By way of non-limiting example, the maximum allowed length may be 25 meters.

As used herein, the phrase “received signal,” when used with reference to a signal used for cable fault detection refers to a signal that is the summation of a periodic signal provided to the cable, e.g., the echo signal, and one or more reflections of the periodic signal.

As used herein, the phrase “magnitude of a pulse” when used with reference to pulses of a signal refers to the absolute value of a measured voltage potential.

Cables, such as network cables, function as electrical transmission lines that may carry power and/or information using electrical currents. If a cable's wiring or insulation is damaged, a cable fault may occur. Two examples of faults that occur in a cable are an open-circuit fault and a short-circuit fault. An open-circuit fault typically occurs when there is a break in the conductor of the cable, or when there is a failure of a connection between a terminal and the cable. A short-circuit fault typically occurs when two conductors of the cable come into contact with each other (directly into contact, or indirectly into contact via an intermediate conductor), as a non-limiting example, due to a failure of the insulation of the cable. Because cables are used extensively in modern infrastructure, cable faults may create wide-spread problems for a multitude of infrastructures and industries. Moreover, cables are often laid underground or are routed through complex objects such as vehicles, making fault identification and repair costly and time-intensive. As such, it is desirable to swiftly and accurately identify a fault type and location to efficiently find, repair, or replace a faulted section of a cable.

Cable fault detection may include locating faults in a cable. One method of cable fault detection involves the use of a time-domain reflectometer (“TDR”). A TDR operates by sending a single pulse of energy along a transmission line, such as a cable. The TDR measures a reflected pulse and time for the reflected pulse to return to estimate a length of a cable, and determines the type and location of the fault in the cable at least partially based on the TDR measurements. The type and location of a fault may be determined using a lookup table that associates TDR measurements with type and/or location of faults in the cable. The associations in the lookup table may be predetermined by testing cables with known faults and associating the fault types and locations with the resulting TDR measurements.

This method of fault detection has several problems that make identifying a fault type (e.g., a short circuit or an open circuit) and location difficult. First, when a cable has multiple connections along its length, reflections from an open circuit in the cable may become attenuated due to the multiple connections creating multiple connections, making the reflections difficult to interpret. Second, when there are multiple connections to the cable, overshoot that occurs on the first pulse edge is difficult to distinguish from multiple reflections resulting from the connections, creating ambiguity in a received reflection. Third, the rules that a TDR uses to detect a fault depend on the location of the fault itself, which is complicated by the huge number of topological possibilities. For example, if a fault is located near an endpoint of a cable, pulse echoes, may interfere with the reflections from the fault. The interference by the pulse echoes may reduce accuracy of TDR measurements and may yield unreliable TDR measurements or fault detection results.

In accordance with the present disclosure, an apparatus is described that provides a periodic signal including pulses where a duration of each of the pulses of the periodic signal is greater than double the time of travel of the pulses along the length of the cable. The apparatus detects a fault in the cable responsive to one or more reflections of the provided periodic signal.

In various examples, the periodic signal may allow for less ambiguity, as compared to a TDR pulse, when analyzing attenuated reflection due to multiple connections and may also reduce the impact of overshoot on the first pulse edge as compared to a TDR pulse, leading to a simpler and more accurate way to identify and locate a cable fault than via TDR.

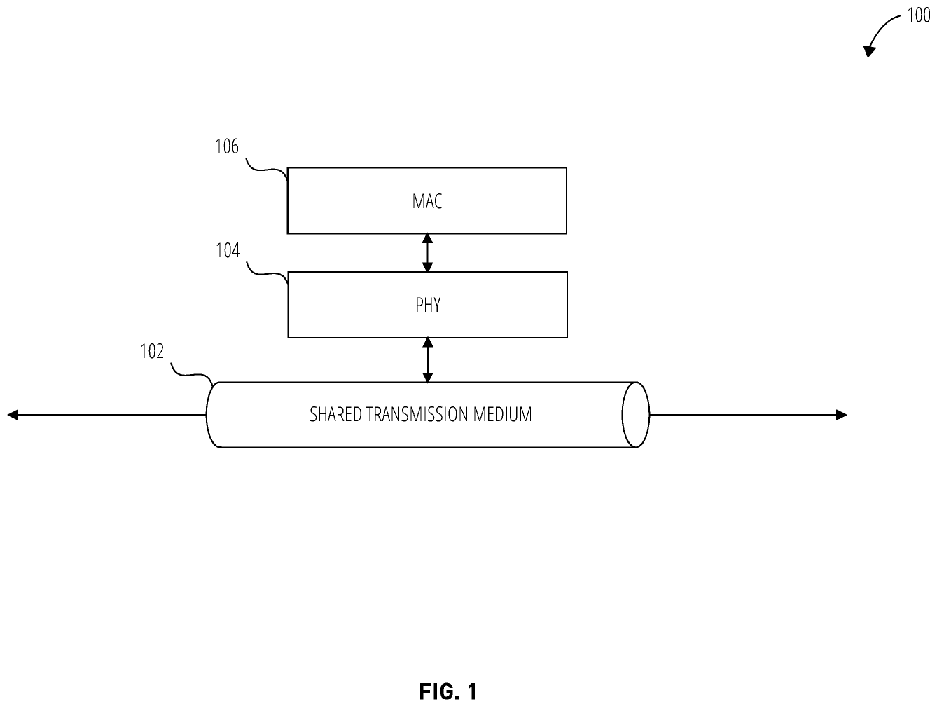

FIG. 1 is a functional block diagram of a network segment 100 including a link layer device, MAC 106, and a physical layer (PHY) device, PHY 104, according to one or more examples. As non-limiting examples, network segment 100 may be a segment of a multidrop network, a segment of a multidrop sub-network, a segment of a mixed media network, or a combination thereof or sub combination thereof. As non-limiting examples, network segment 100 may be, may be part of, or include one or more of a microcontroller-type embedded system, a user-type computer, a computer server, a notebook computer, a tablet, a handheld device, a mobile device, a wireless earbud device or headphone device, a wired earbud or headphone device, an appliance sub-system, lighting sub-system, sound sub-system, building control systems, residential monitoring system (e.g., for security or utility usage, without limitation) system, elevator system or sub-system, public transit control system (e.g., for above ground train, below ground train, trolley, or bus, without limitation), an automobile system or automobile sub-system, or an industrial control system, without limitation.

PHY 104 may interface with MAC 106. As non-limiting examples, PHY 104 and/or MAC 106 may be chip packages including memory and/or logic configured for carrying out all or portions of examples described herein. As non-limiting examples, PHY 104 and MAC 106, respectively, may be implemented as separate chips or circuitry (e.g., integrated circuits) in a single chip package (e.g., a system-in-a-package (SIP)).

PHY 104 also interfaces with shared transmission medium 102, a physical medium that is a communication path for nodes that are part of network segment 100 or a network of which network segment 100 is a part, including nodes that include instances of PHY 104 and MAC 106. As a non-limiting example, shared transmission medium 102 may be a single twisted pair such as used for single pair Ethernet, such as 10BASE-T1S, a network technology specified in IEEE 802.3cg™.

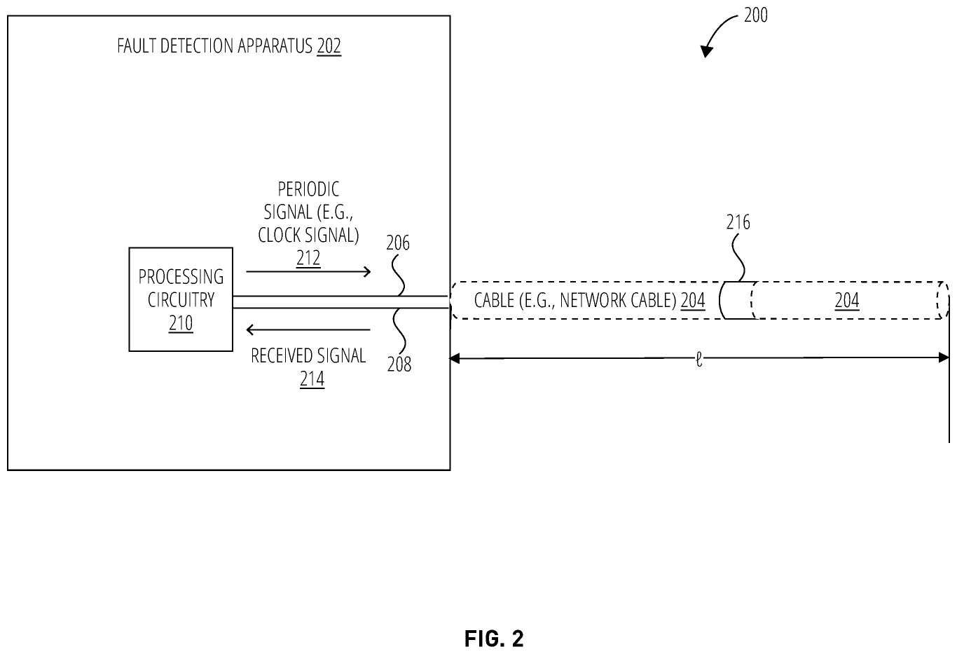

FIG. 2 shows a fault detection system 200 according to one or more examples. The fault detection system may include fault detection apparatus 202 and a cable (e.g., network cable) 204. The fault detection apparatus 202 may include processing circuitry 210 that is electrically connected to the cable 204 via a first pair of terminals 206 and a second pair of terminals 208. Though first terminals 206 and second terminals 208 are depicted by FIG. 2 as different terminals, this is merely to more easily differentiate between periodic signal 212 and received signal 214 in the discussion, and first terminals 206 and second terminals 208 may be the same or different terminals, without exceeding the scope. In some embodiments, the first terminals 206 and the second terminals 208 may be in the form of input/output terminals where the fault detection system 200 may include any number of input/output terminals. For example, the fault detection system 200 may include one input/output terminal for each conductor included in the cable 204. As a specific non-limiting example, the first terminals 206 may provide a periodic signal (e.g., periodic signal 212) to a first conductor of the cable and where the second terminals 208 may provide a complementary periodic signal (e.g., a signal having a waveform mirroring the periodic signal) to a second conductor of the cable. In some embodiments, processing circuitry 210 provides periodic signal 212 to the cable 204 via the first terminals 206, as a differential signal, and receives the received signal 214 from the cable 204 via the second terminals 208. Processing circuitry 210 may receive (e.g., through the second terminals 208) one or more reflections of the periodic signal 212 provided to the cable 204 in the received signal 214, as well as an echo signal of the periodic signal 212. In a non-limiting example, the one or more reflections may be the result of the provided periodic signal 212 encountering a fault 216 in cable 204. In one or more examples, fault 216 may be an open circuit in cable 204. In other examples, fault 216 may be a short circuit in cable 204.

Processing circuitry 210 may receive received signal 214, where received signal 214 is the provided periodic signal 212, i.e., the echo signal, plus the one or more reflections of the periodic signal 212. In one or more examples, processing circuitry 210 may be a signal generator to provide (e.g., through the first terminals 206) a clock signal as periodic signal 212 to cable 204 and also receive one or more reflections from the clock signal as the received signal 214 where the received signal 214 may be the resulting summation of the periodic signal 212 plus the one or more reflections of the periodic signal 212. The processing circuitry 210 may detect a fault in the cable 204 responsive to the received signal 214 received at the second terminals 208.

Cable 204 may be of a maximum allowed length f as shown in FIG. 2, where the maximum allowed length f may be, by way of non-limiting example, substantially 25 meters. The actual length of the cable 204 may be less than or equal to the maximum allowed length f.

In other examples, the maximum allowed length f may be of any length specified by a standard governing the fault detection system 200. Furthermore, the cable 204 may be a network cable such as a shared transmission medium 102 of a wired local area network as shown in FIG. 1.

In one or more examples the fault detection apparatus 202 may be implemented within a processing circuit such as a microcontroller. In one or more examples the fault detection apparatus 202 may be implemented within a physical layer device such as the PHY 104 of FIG. 1. In some such examples the second terminals 208 and the first terminals 206 may include integrated circuit device connections, terminals or pins.

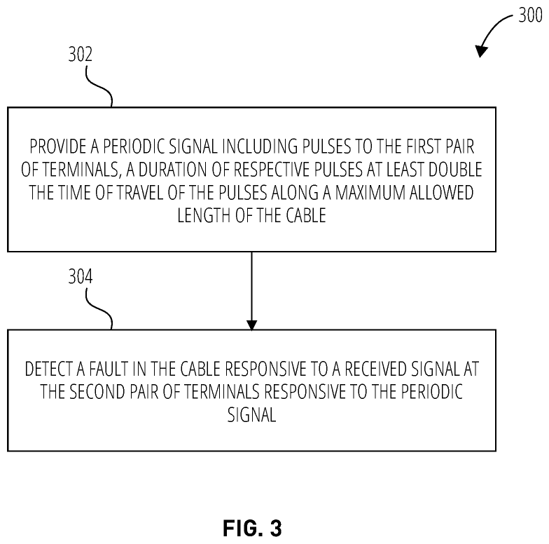

FIG. 3 is a flowchart illustrating a method 300 of detecting a fault in a cable according to one or more examples. In one or more examples, method 300 may be performed by a device or system, such as fault detection apparatus 202 (see FIG. 2). In operation 302, method 300 provides a periodic signal (e.g., the periodic signal 212 of FIG. 2) that includes positive going pulses and negative going pulses to a first pair of terminals (e.g., the first terminals 206 of FIG. 2), which may be electrically connected to a cable (e.g., cable 204 of FIG. 2). The duration of respective pulses of the periodic signal is at least double the time of travel of the pulses along a maximum allowed length of the cable (e.g., 25 meters). In operation 304, method 300 detects a fault (e.g., fault 216 of FIG. 2) in the cable responsive to a received signal (e.g., received signal 214 of FIG. 2) at a second pair of terminals (e.g., the second terminals 208 of FIG. 2) responsive to the periodic signal. As previously discussed, a “received signal” includes the periodic signal and one or more reflections generated responsive to the periodic signal, and the first terminals may be the same as the second terminals.

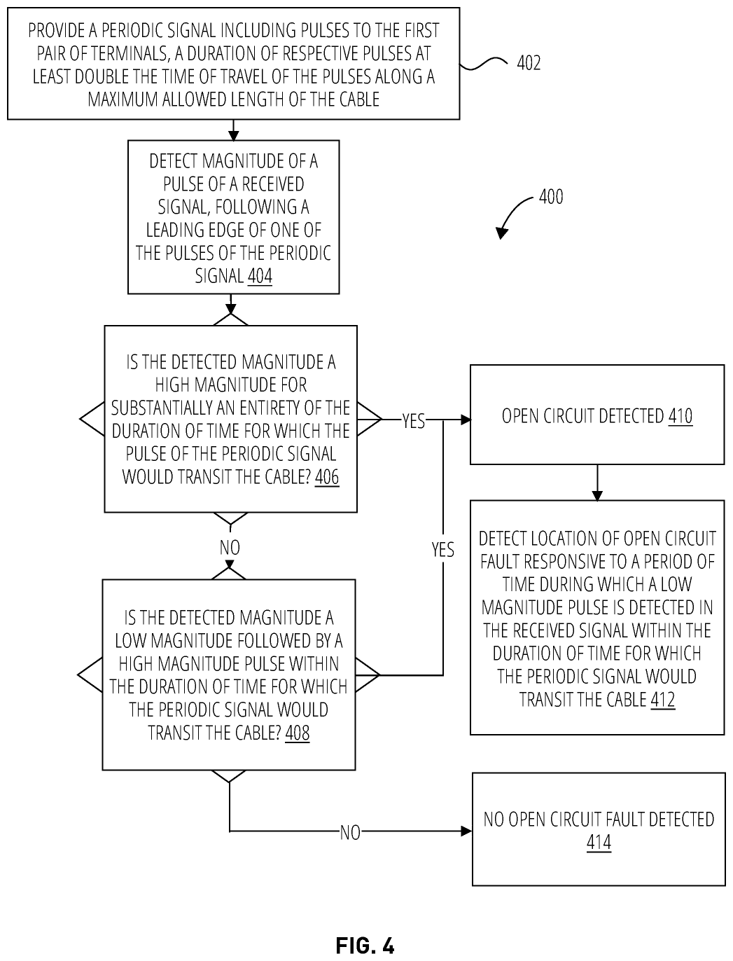

FIG. 4 is a flowchart illustrating a method 400 of detecting an open circuit in a cable, according to one or more examples. In operation 402, method 400 provides a periodic signal (e.g., the periodic signal 212 of FIG. 2) that includes pulses to a first terminals (e.g., the first terminals 206 of FIG. 2), which may be electrically connected to a cable (e.g., the cable 204 of FIG. 2) where a duration of respective pulses of the periodic signal is at least double the time of travel of the pulses along a maximum allowed length of the cable. In one or more examples, the maximum allowed length of the cable is 25 meters. In one or more examples, the cable is a shared transmission medium (e.g., the shared transmission medium 102 of FIG. 1). In operation 404, method 400 detects a magnitude of a pulse of a received signal (e.g., the received signal 214 of FIG. 2) following a leading edge of one of the pulses of the periodic signal. In one or more examples, the received signal is the periodic signal plus one or more reflections of the periodic signal.

Following operation 404, method 400 may then proceed to operation 406. In operation 406, method 400 determines whether the magnitude detected in operation 404 is a high magnitude for substantially an entirety of the duration of time for which the pulse of the periodic signal would transit the cable. As used herein, a “high magnitude” or a “high magnitude pulse” is a detected magnitude or pulse having a magnitude greater than a high threshold, which high threshold is higher than a magnitude of the pulses of the periodic signal (i.e., the echo signal). As used herein, the phrase “the cable” refers to the maximum allowed length of the cable, since the actual length of the cable may be unknown. If a high magnitude is detected for substantially an entirety of the duration of the pulse of the periodic signal, then the method proceeds to operation 410 where the method 400 detects an open circuit in the cable. If not, then the method continues to operation 408.

In operation 408, method 400 determines whether the magnitude detected in operation 404 is a low magnitude, followed by a high magnitude pulse within the duration of the pulse of the periodic signal. As used herein, a “low magnitude” or a “low magnitude pulse” is a detected magnitude or pulse having a magnitude lower than a low threshold, which may be substantially zero. If a low magnitude pulse followed by a high magnitude pulse is detected, then the proceeds to operation 410 where the method 400 detects an open circuit in the cable. If not, then the method continues to operation 414 where the method 400 determines that no open circuit fault is detected in the cable.

In one example the high threshold is higher than a magnitude of the pulses of the periodic signal and the low threshold is substantially zero. In another example, multiple tests on multiple sample cables, with predetermined faults, are run to determine appropriate thresholds.

In operation 410, method 400, if having proceeded through either operation 406 or operation 408, detects an open circuit in the cable. The method 400 may then proceed to operation 412. In operation 412, method 400 detects a location of the detected open circuit in the cable responsive to a period of time beginning at the leading edge of the periodic signal during which a low magnitude pulse is detected in the received signal within the duration of the pulse of the periodic signal. For example, in operation 412, the location of the detected open circuit may be located at a point along the cable that is a distance from a point of connection between the cable and the first terminal along the length of the cable where the distance may be calculated based on a period of time beginning at a leading edge of a pulse during which a low magnitude pulse is detected in the received signal. In a non-limiting example, if method 400 proceeds through operation 406 in which a high magnitude pulse is detected in the received signal for substantially an entirety of a duration of time of a pulse of the periodic signal following the leading edge of the pulse, operation 412 may locate the fault as being substantially zero meters away from the point of connection between the cable and the first terminal. Stated another way, in operation 412, method 400 locates a fault based on the period of time a low magnitude pulse is detected within the duration of the pulse of the periodic signal, which, as a non-limiting example, in the case of proceeding through operation 406, would be zero. In another non-limiting example, if method 400 proceeds through operation 408 in which a low magnitude pulse is detected in the received signal followed by a high magnitude pulse in the received signal within the duration of the pulse of the periodic signal following the leading edge, operation 412 may locate the fault as being along the length of the cable at a distance away from the point of connection between the first terminals and the cable and where the distance is calculated based on the amount of time within the duration of the pulse of the periodic signal during which the low magnitude pulse is detected in the received signal.

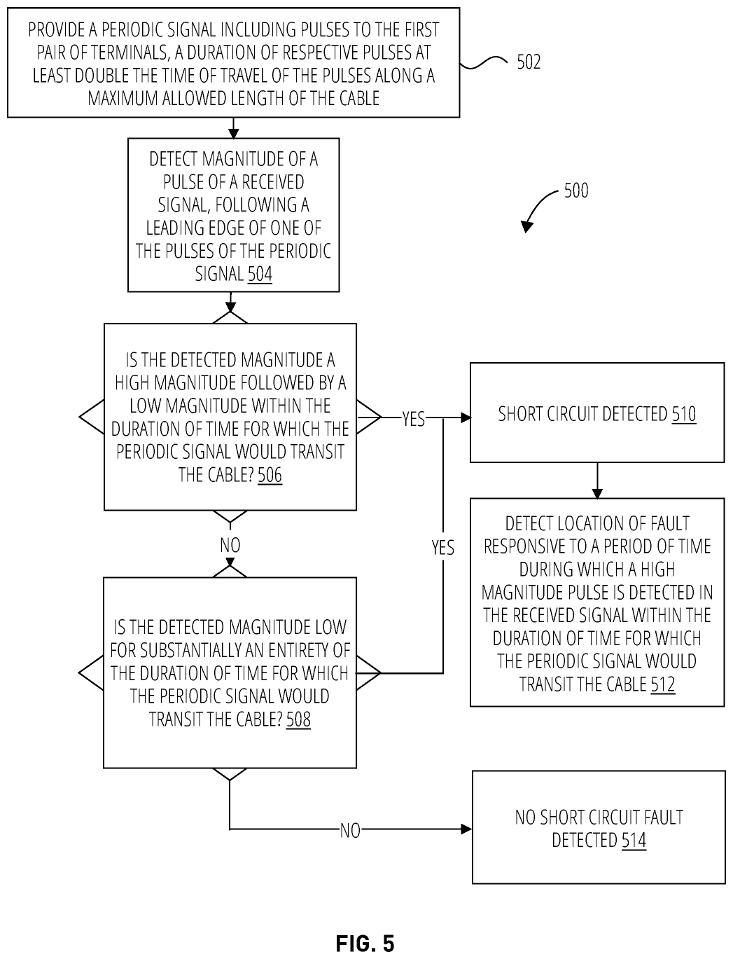

FIG. 5 is a flowchart illustrating a method 500 of detecting a short circuit in a cable (e.g., cable 204), according to one or more examples. In operation 502, method 500 provides a periodic signal (e.g., the periodic signal 212 of FIG. 2) that includes pulses to the first terminals (e.g., the first terminals 206 of FIG. 2), which may be electrically connected to the cable where a duration of each pulse is at least double the time of travel of the pulses along a maximum allowed length of the cable. In one or more examples the maximum allowed length of the cable is 25 meters. In one or more examples the cable is a shared transmission medium (e.g., the shared transmission medium 102 of FIG. 1). In operation 504, method 500 detects a magnitude of a received signal (e.g., the received signal 214 of FIG. 2) following a leading edge of one of the pulses of the periodic signal (i.e., the echo signal). In one or more examples, the received signal is the periodic signal plus one or more reflections of the periodic signal.

Following operation 504, method 500 may then proceed to operation. In operation 506, method 500 checks whether the magnitude detected in operation 504 is a high magnitude followed by a low magnitude within the duration of the pulse of the periodic signal. If yes, then the method 500 proceeds to operation 510. If no, then the method 500 continues to operation 508.

In operation 508, method 500 checks whether the magnitude detected in operation 504 is of a low magnitude for substantially an entirety of the duration of the pulse of the periodic signal. If no, then the method 500 continues to operation 514 and no short circuit fault is detected in the cable. If yes, then the method 500 continues to operation 510.

In operation 510, method 500, having moved through either operation 506 or operation 508, detects a short circuit in the cable. In operation 512, method 500 detects a location of the detected short circuit in the cable responsive to a period of time beginning at the leading edge of the periodic signal during which a high magnitude pulse is detected in the received signal. In a non-limiting example, if method 500 proceeds through operation 506, in which a low magnitude pulse is detected in the received signal for substantially an entirety of the duration of the pulse of the periodic signal, operation 512 may locate the fault as being substantially zero meters away from the point of connection between the cable and the first terminals. Stated another way, in operation 512, method 500 locates a fault based on the period of time a high magnitude pulse is detected within the duration of the pulse of the periodic signal, which, as a non-limiting example, in the case of proceeding through operation 506, would be zero. As another non-limiting example, if method 500 proceeds through operation 508, in which a high magnitude pulse is detected in the received signal following the leading edge of one of the pulses of the periodic signal, followed by a low magnitude pulse in the received signal, while within the duration of the pulse of the periodic signal, operation 512 may locate the fault as being greater than zero meters away from the point of connection between the cable and the first terminal responsive to the amount of time during with the high magnitude pulse is detected in the received signal.

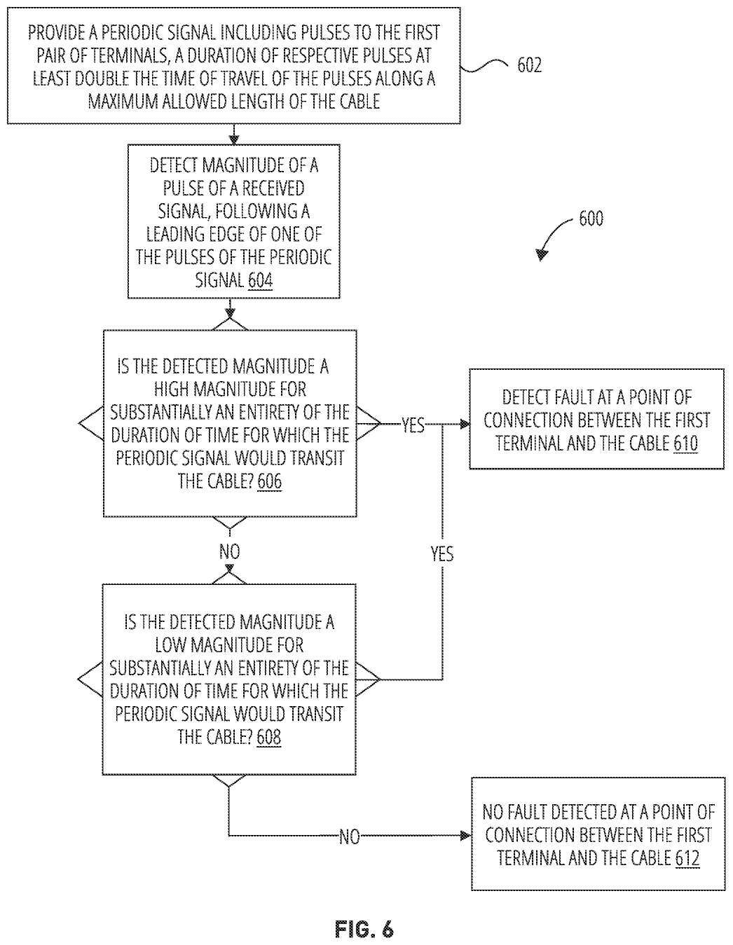

FIG. 6 is a flowchart illustrating a method 600 of detecting a fault (e.g., the fault 216 of FIG. 2) in a cable (e.g., the cable 204 of FIG. 2) at a point of connection between a first terminal (e.g., the first terminal 206 of FIG. 2) and the cable electrically connected to the first terminal. In operation 602, method 600 provides a periodic signal that includes pulses to the first terminal where a duration of each pulse is at least double the time of travel of the pulses along a maximum allowed length of the cable. In one or more examples the maximum allowed length of the cable is 25 meters. In one or more examples the cable is a shared transmission medium (e.g., the shared transmission medium 102 of FIG. 1). In operation 604, method 600 detects a magnitude of a pulse of a received signal following a leading edge of one of the pulses of the periodic signal. In one or more examples, the received signal is the periodic signal plus one or more reflections of the periodic signal.

Following operation 604, method 600 may then proceed to operation 606. In operation 606, method 600 checks whether the magnitude detected in operation 604 is a high magnitude for substantially an entirety of a duration of a pulse of the periodic signal. If yes, then the method 600 proceeds to operation 610. If no, then the method 600 continues to operation 608. In operation 608, method 600 checks whether the magnitude detected in operation 604 is a low magnitude for substantially an entirety of a duration of a pulse of the periodic signal. If no, then the method 600 continues to operation 612 and no fault is detected at a point of connection between the first terminal and the cable. If yes, then the method 600 continues to operation 610. In operation 610, method 600, having moved through either operation 606 or 608 detects a fault in the cable at a point of connection between the first terminal and the cable.

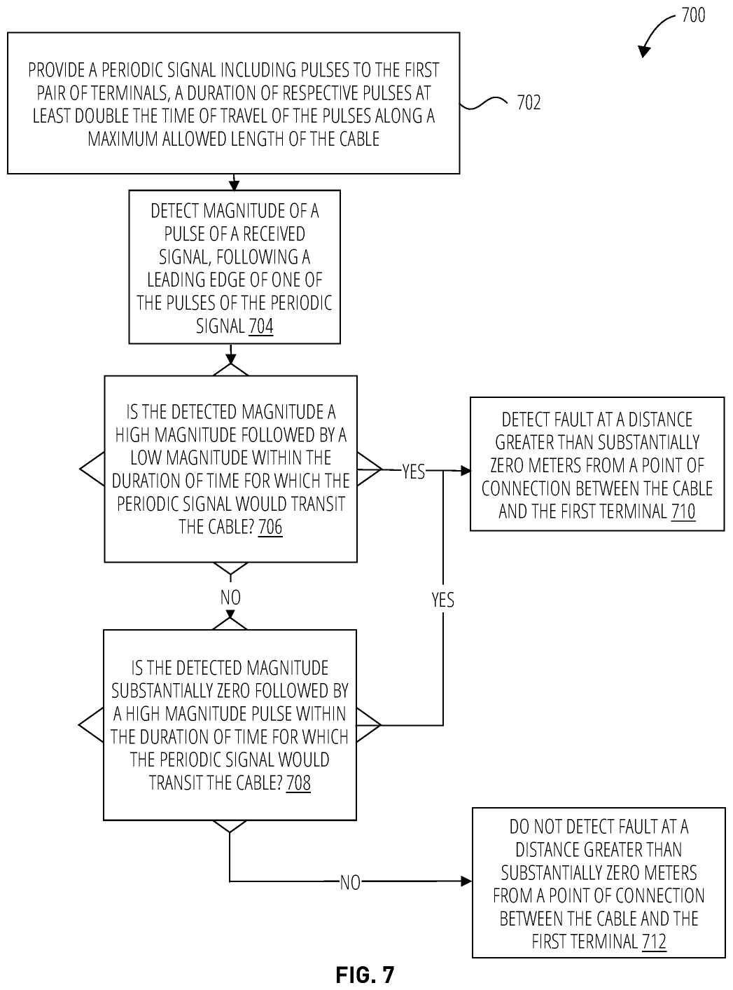

FIG. 7 is a flowchart illustrating a method 700 of detecting a fault (e.g., the fault 216 of FIG. 2) in a cable (e.g., the cable 204 of FIG. 2) at a distance greater than substantially zero meters from a point of connection between a first terminal (e.g., the first terminal 206 of FIG. 2) and the cable electrically connected to the first terminal. In operation 702, method 700 provides a periodic signal (e.g., periodic signal 212 of FIG. 2) that includes pulses to the first terminals, where a duration of each pulse is at least double the time of travel of the pulses along a maximum allowed length of the cable. In one or more examples the maximum allowed length of the cable is 25 meters. In one or more examples the cable is a shared transmission medium (e.g., the shared transmission medium 102 of FIG. 1). In operation 704, method 700 detects a magnitude of a received signal (e.g., received signal 214 of FIG. 2) following a leading edge of one of the pulses of the periodic signal. In one or more examples, the received signal is the periodic signal plus one or more reflections of the periodic signal.

Following operation 704, method 700 may then proceed to operation 706. In operation 706, method 700 checks whether the magnitude detected in operation 704 is a high magnitude followed by a low magnitude within a duration of a pulse of the periodic signal. If yes, then the method 700 proceeds to operation 710. If no, then the method 700 continues to operation 708.

In operation 708, method 700 checks whether the magnitude detected in operation 704 is a high magnitude followed by a low magnitude within the duration of the pulse of the periodic signal. If no, then the method 700 proceeds to operation 712 and no fault is detected at a distance greater than substantially zero meters from a point of connection between the cable and the first terminal. If yes, then the method 700 proceeds to operation 710. In operation 710, method 700, having moved through either operation 706 or 708, detects a fault in the cable at a distance greater than substantially zero meters from a point of connection between the cable and the first terminal.

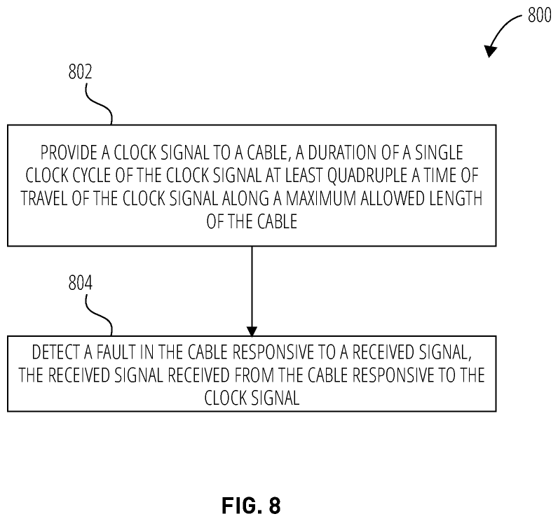

FIG. 8 is a flowchart illustrating a method 800 of detecting a fault (e.g., fault 216 of FIG. 2) in a cable (e.g., cable 204 of FIG. 2) according to one or more examples. In operation 802, method 800 provides a clock signal to a cable (e.g., cable 204 of FIG. 2) where a duration of a single clock cycle of the clock signal is at least quadruple a time of travel of a pulse of the clock signal along a maximum length of the cable. In operation 804, method 800 detects a fault in the cable responsive to a received signal, the received signal received from the cable responsive to the clock signal.

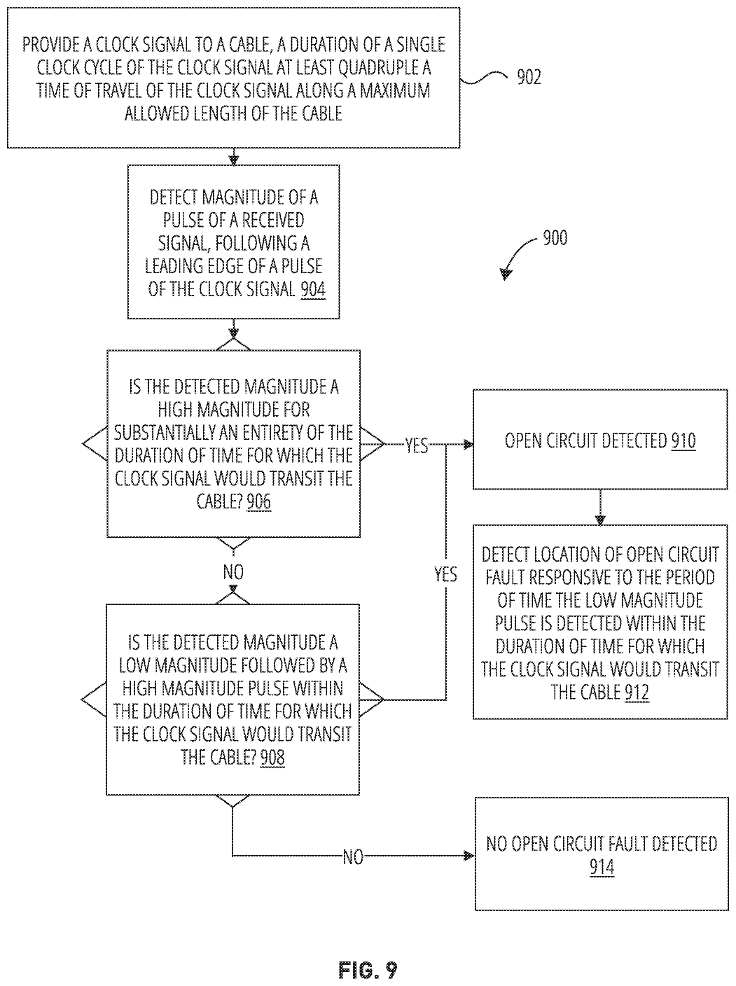

FIG. 9 is a flowchart illustrating a method 900 of detecting an open circuit in a cable (e.g., cable 204 of FIG. 2), according to one or more examples. In operation 902, method 900 provides a clock signal to a cable where a duration of a single clock cycle is at least quadruple the time of travel of a pulse of the clock signal along a maximum allowed length of the cable. In one or more examples the clock signal may be a low-frequency clock signal. In one or more examples the maximum allowed length of the cable is 25 meters. In one or more examples the cable is a shared transmission medium (e.g., the shared transmission medium 102 of FIG. 1). In operation 904, method 900 detects a magnitude of a received signal following a leading edge of a pulse of the clock signal. Each pulse of the clock signal may correspond to a first logic level of a clock signal. In one or more examples, the received signal is the clock signal plus one or more reflections of the clock signal.

Following operation 904, method 900 may then proceed to operation 906. In operation 906, method 900 checks whether the magnitude detected in operation 904 is a high magnitude (i.e., a magnitude greater than a high threshold, which high threshold is higher than a magnitude of the pulses of the clock signal) for substantially an entirety of the duration of the pulse of the clock signal. If yes, then the method 900 proceeds to operation 910. If no, then the method 900 continues to operation 908. In operation 908, method 900 checks whether the magnitude detected in operation 904 is a low magnitude (i.e., a magnitude lower than a low threshold, which low threshold may be substantially zero) followed by a high magnitude pulse in the received signal, while within the duration of the pulse of the clock signal following a leading edge of the clock signal. If no, then the method continues to operation 914 and no open circuit fault is detected in the cable. If yes, then the method 900 continues to operation 910.

In operation 910, method 900, having moved through either operation 906 or operation 908, detects an open circuit in the cable. In operation 912, method 900 detects a location of the detected open circuit in the cable responsive to a period of time beginning at the leading edge of a pulse of the clock signal during which a low magnitude pulse is detected in the received signal. For example, in operation 910, the location of the detected open circuit may be located at a point in the cable that is a distance from the connection point between the cable and the first terminal where the distance may be calculated based on a period of time beginning at a leading edge of a pulse of the clock signal during which a low magnitude pulse is detected in the received signal. In a non-limiting example, if method 900 proceeds through operation 906, in which a high magnitude pulse is detected in the received signal for substantially an entirety of the duration of the pulse of the clock signal, operation 912 may locate the fault as being substantially zero meters away from the point of connection between the cable and the first terminal. Stated another way, in operation 912, method 900 locates a fault based on the period of time a low magnitude pulse is detected within the duration of the pulse of the clock signal, which, in the case of proceeding through operation 906, would be zero. As another non-limiting example, if method 900 proceeds through operation 908, in which there is a low magnitude pulse detected in the received signal within the duration of the pulse of the clock signal, followed by a high magnitude pulse in the received signal, while within the duration of the pulse of the clock signal, operation 912 may locate the fault as being greater than zero meters away from the point of connection between the cable and the first terminal, based on the period of time the slow magnitude pulse is detected within the duration of the pulse of the clock signal.

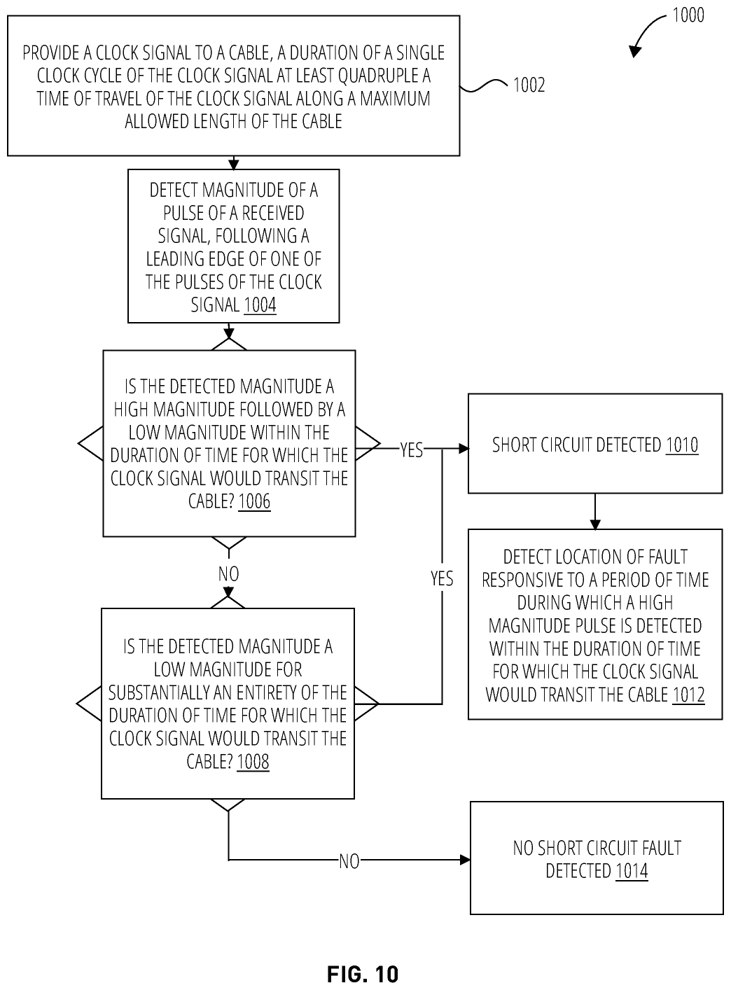

FIG. 10 is a flowchart illustrating a method 1000 of detecting an open circuit in a cable (e.g., cable 204 of FIG. 2) in response to one or more reflections of a clock signal according to one or more examples. In operation 1002, method 1000 provides a clock signal to a cable where a duration of a single clock cycle is at least quadruple the time of travel of a pulse of the clock signal along a maximum allowed length of the cable. In one or more examples the clock signal may be a low-frequency clock signal. In one or more examples the maximum allowed length of the cable is 25 meters. In one or more examples the cable is a shared transmission medium (e.g., the shared transmission medium 102 of FIG. 1). In operation 1004, method 1000 detects a magnitude of a received signal following a leading edge of a pulse of the clock signal. In one or more examples, the received signal is the clock signal plus one or more reflections of the clock signal.

Following operation 1004, method 1000 may then proceed to operation 1006. In operation 1006, method 1000 checks whether the magnitude detected in operation 1004 is a high magnitude followed by a low magnitude within the duration of the pulse of the clock signal. If yes, then the method 1000 proceeds to operation 1010. If no, then the method 1000 continues to operation 1008. In operation 1008, method 1000 detects a high magnitude pulse in the received signal within the duration of the pulse of the clock signal, followed by a low magnitude pulse in the received signal, while within the duration of the pulse of the clock signal. If yes, then the method 1000 proceeds to operation 1010. If no, then the method 1000 continues to operation 1014 and no short circuit fault is detected in the cable.

In operation 1010, method 1000, having moved through either operation 1006 or operation 1008, detects a short circuit in the cable. In operation 1012, method 1000 detects a location of the detected short circuit in the cable responsive to a period of time beginning at the leading edge of a pulse of the clock signal during which a high magnitude pulse is detected in the received signal. For example, in operation 1010, the location of the detected short circuit may be located at a point in the cable that is a distance from the connection point between the cable and the first terminal where the distance may be calculated based on a period of time beginning at a leading edge of a pulse of the clock signal during which a high magnitude pulse is detected in the received signal. In a non-limiting example, if method 1000 proceeds through operation 1006, in which a low magnitude pulse is detected in the received signal for substantially an entirety of the duration of the pulse of the clock signal, operation 1012 may locate the fault as being substantially zero meters away from the point of connection between the cable and the first terminal. Stated another way, in operation 1012, method 1000 locates a fault based on the period of time a high magnitude pulse is detected within the duration of the pulse of the clock signal, which, in the case of proceeding through operation 1006, would be zero. In another example, if method 1000 proceeds through operation 1008, in which a high magnitude pulse is detected in the received signal within the duration of the pulse of the clock signal, followed by a low magnitude pulse in the received signal, while within the duration of the pulse of the periodic signal, operation 1012 may locate the fault as being greater than zero meters from the point of connection between the cable and the first terminal, the location based on the period of time the high magnitude pulse is detected within the duration of the pulse of the clock signal.

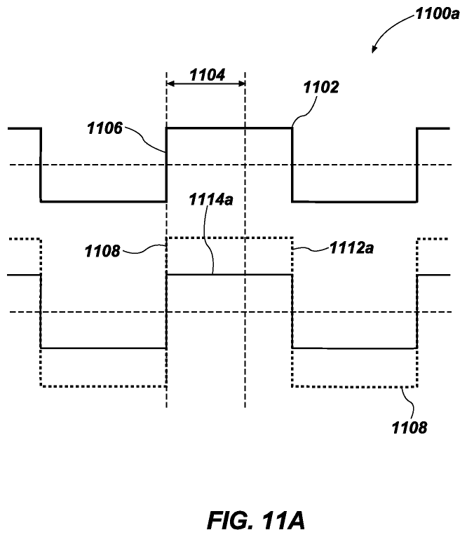

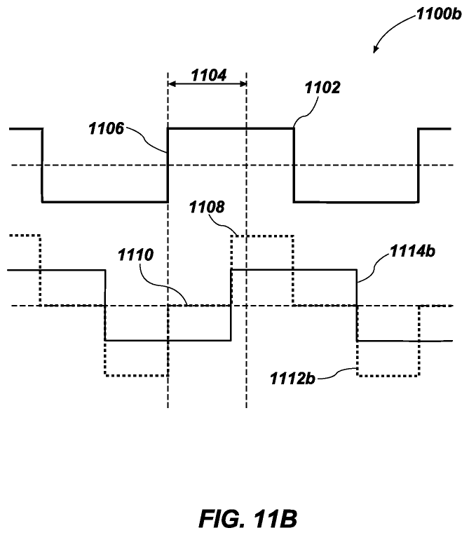

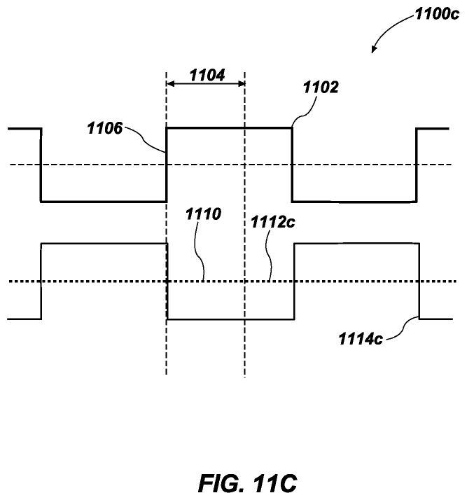

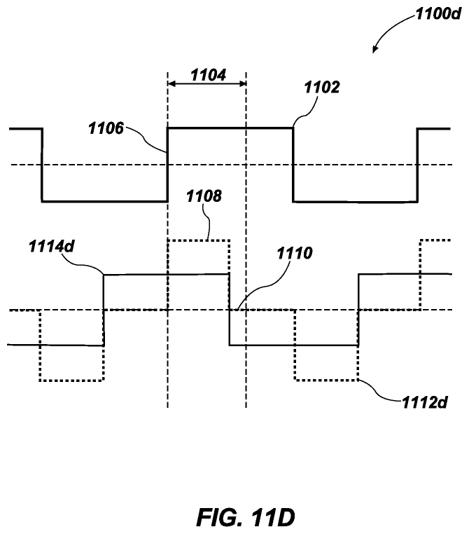

FIG. 11A is an example of a signal timing diagram 1100a illustrating signals of the fault detection system 200 of FIG. 2 where an open circuit fault is located substantially zero meters from a connection point between a cable and a first terminal. Signal timing diagram 1100a illustrates a periodic signal 1102 and one or more reflections 1114a of the periodic signal 1102 and a received signal 1112a.

In one or more examples, the received signal 1112a is the sum of the periodic signal 1102 (i.e., the echo signal) and the one or more reflections 1114a. Furthermore, signal timing diagram 1100a also includes a period of time 1104, which represents a duration of the maximum amount of time that a pulse of the periodic signal may take to traverse the cable and return, i.e., a round trip time, which is the period of time in which a processing circuitry (e.g., processing circuitry 210 in FIG. 2) may detect the magnitude of the received signal 1112a beginning at a leading edge 1106 of periodic signal 1102. In one or more examples, the period of time 1104 represents double a time of travel of pulses of the periodic signal 1102 along a maximum length of the cable. In one or more examples, a leading edge 1106 may be either a rising or a falling edge of the periodic signal 1102. In one or more examples, the periodic signal 1102 may be in the form of a clock signal.

As shown in FIG. 11A, the periodic signal 1102 may have a duty cycle that is substantially 50%. Moreover, in one or more examples, the pulses of the received signal 1112a may be in the form of a high magnitude pulse 1108 where the magnitude of the high magnitude pulse 1108 is greater than a high threshold, which high threshold is higher than the magnitude of a corresponding pulse of the periodic signal 1102.

As may be seen in FIG. 11A, the summation of the periodic signal 1102 and the one or more reflections 1114a creates a signal pattern of the received signal 1112a that is detected during the period of time 1104 following a leading edge 1106 of the periodic signal 1102. For example, signal timing diagram 1100a includes a diagram of multiple signals, one being the periodic signal 1102, one being one or more reflections 1114a, as well as the resulting received signal 1112a.

In one or more examples, a processing circuitry (e.g., processing circuitry 210) may detect both the type of fault (e.g., open or short) and the location of the fault along a cable that the periodic signal is provided to responsive to the signal pattern exhibited by a received signal (e.g., received signal 1112a) within the period of time 1104. For instance, in the example depicted in signal timing diagram 1100a, an open circuit at a distance of substantially zero meters may be detected if, within the period of time 1104, a high magnitude pulse 1108 is detected for substantially an entirety of the period of time 1104, which high magnitude pulse represents the periodic signal 1102 plus the reflection from the open connection at zero meters, as represented by one or more reflections 1114a, which is therefore coincidental with the periodic signal 1102.

FIG. 11B is an example of a signal timing diagram 1100b illustrating signals of the fault detection system 200 of FIG. 2 where an open circuit is located at a distance greater than substantially zero meters from a connection point between a cable and a first terminals. Signal timing diagram 1100b illustrates a periodic signal 1102 and one or more reflections 1114b of the periodic signal 1102 and a received signal 1112b.

The received signal 1112b and one or more reflections 1114b may be identical to the received signal 1112a and one or more reflections 1114a shown in FIG. 11A, respectively, but for the differing signal patterns including the differing signal patterns detected within the period of time 1104. As shown in the example depicted in signal timing diagram 1100b, an open circuit at a distance greater than substantially zero meters from a connection point between a cable and a first terminal may be detected if, within the period of time 1104, a low magnitude pulse 1110 is detected followed by a high magnitude pulse 1108. The one or more reflections 1114b at the rising edge of periodic signal 1102 represent a previous negative going portion of periodic signal 1102 reflected back by the open connection. Thus, at the rising edge of periodic signal 1102, the one or more reflections 1114b reduce the magnitude of the received signal 1112b. Since the pulse width is greater than a maximum round trip time, at least some of the one or more reflections 1114b are coincident with the positive portion of periodic signal 1102, as the rising edge of periodic signal 1102, after delay by the round trip time from the open connection is received as part of the received signal 1112b as indicated by high magnitude pulse 1108.

FIG. 11C is an example of a signal timing diagram 1100c illustrating signals of the fault detection system 200 of FIG. 2 where a short circuit is located substantially zero meters from a connection point between a cable and a first terminal. Signal timing diagram 1100c illustrates a periodic signal 1102 and one or more reflections 1114c of the periodic signal 1102 and a received signal 1112c.

The received signal 1112c and one or more reflections 1114c may be identical to the received signal 1112a and one or more reflections 1114a shown in FIG. 11A, respectively, but for the differing signal patterns including the differing signal patterns detected within the period of time 1104. As shown in the example depicted in signal timing diagram 1100c, a short circuit located substantially zero meters from a connection point between a cable and a first terminal may be detected if, within the period of time 1104, a low magnitude pulse 1110 is detected, since a short circuit will provide an inverted signal (the positive and negative wires are shorted as one or more reflections 1114c), substantially aligned in time with periodic signal 1102.

FIG. 11D is an example of a signal timing diagram 1100d illustrating signals of the fault detection system 200 of FIG. 2 where an open circuit is located at a distance greater than substantially zero meters from a connection point between a cable and a first terminal. Signal timing diagram 1100d illustrates a periodic signal 1102 and one or more reflections 1114d of the periodic signal 1102 and a received signal 1112d.

The received signal 1112d and one or more reflections 1114d may be identical to the received signal 1112a and one or more reflections 1114a shown in FIG. 11A, respectively, but for the differing signal patterns including the differing signal patterns detected within the period of time 1104. As shown in the sample depicted in signal timing diagram 1100d, an open circuit located at a distance greater than substantially zero meters from a connection point between a cable and a first terminal may be detected if, within the period of time 1104, a high magnitude pulse 1108 is detected followed by a low magnitude pulse 1110. The one or more reflections 1114d at the rising edge of periodic signal 1102 represent a previous negative going portion of periodic signal 1102 reflected back, and inverted, by the short connection. Thus, at the rising edge of periodic signal 1102, the one or more reflections 1114d add to the magnitude of the received signal 1112d. Since the pulse width is greater than a maximum round trip time, at least some of the one or more reflections 1114d or the positive going portion of periodic signal 1102, inverted, are coincident with the positive portion of periodic signal 1102, as shown by the falling edge of the high magnitude pulse 1108.

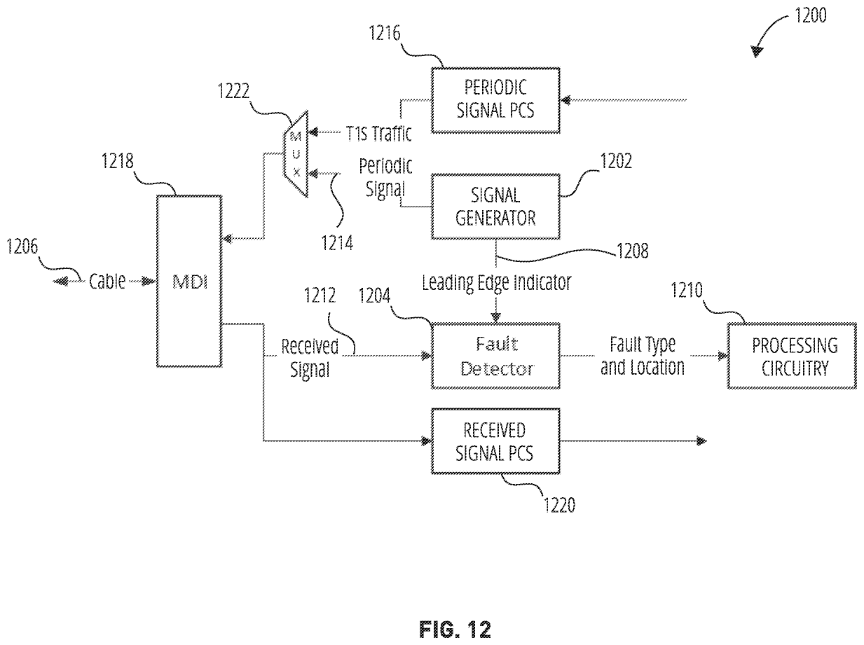

FIG. 12 is a block diagram of a fault detection system 1200, according to one or more examples. Fault detection system 1200 may include a signal generator 1202, a cable 1206, a periodic signal PCS (physical coding sublayer) 1216, a received signal PCS 1220, a medium dependent interface (MDI) 1218, a multiplexer (MUX) 1222, a processing circuitry 1210, and a fault detector 1204.

In one or more examples, signal generator 1202 may provide a periodic signal 1214 to cable 1206 through MUX 1222 and MDI 1218. In one or more examples, the signal generator 1202 may be in the form of a clock signal generator that may provide a clock signal to cable 1206 through MUX 1222 and MDI 1218. In one or more examples, fault detector 1204 may receive a received signal 1212 where, in one or more examples, received signal 1212 is the sum of the periodic signal 1214 plus one or more reflections of the periodic signal 1214. In one or more examples, signal generator 1202 may also provide a leading edge indicator 1208 to fault detector 1204 where fault detector 1204 may receive the leading edge indicator 1208 from the signal generator 1202. In one or more examples, the fault detector 1204 may detect a leading edge of the periodic signal 1214 responsive to received signal 1212, and leading edge indicator 1208 may not be provided, or may be generated by fault detector 1204. In one or more examples, the leading edge indicator 1208 may be an indication of a rising or a falling edge of periodic signal 1214.

In one or more examples, fault detector 1204 may determine a fault type and location based, at least in part, on the received signal 1212 and the leading edge indicator 1208. For example, fault detector 1204 may begin detecting a magnitude of the received signal 1212 where the detecting begins at a leading edge of periodic signal 1214 according to the leading edge indicator 1208. Fault detector 1204 may then detect a fault type and location based on the detected magnitude of the received signal 1212. In one or more examples, fault detector 1204 may then provide the detected fault type and location to processing circuitry 1210. It will be appreciated that the signal generator 1202, fault detector 1204, and processing circuitry 1210 may, in one or more examples, be a single processor to execute the aforementioned functions.

The periodic signal PCS 1216 and received signal PCS 1220 may provide data encoding, decoding, scrambling, descrambling or perform alignment marker insertion and removal as well as perform lane block synchronization and de-skewing. The periodic signal PCS 1216 may also provide T1S traffic to the MUX 1222. The MUX 1222 may take multiple input connections and select which of the input connections to pass through to an output. For example, the MUX 1222 may select whether the T1S traffic provided by the periodic signal PCS 1216 or the periodic signal 1214 provided by the signal generator 1202 will be passed through to the MDI 1218. The MDI 1218 may be an interface between a physical layer implementation (e.g., T1S traffic or periodic signal 1214) to a physical transmission medium (e.g., cable 1206).

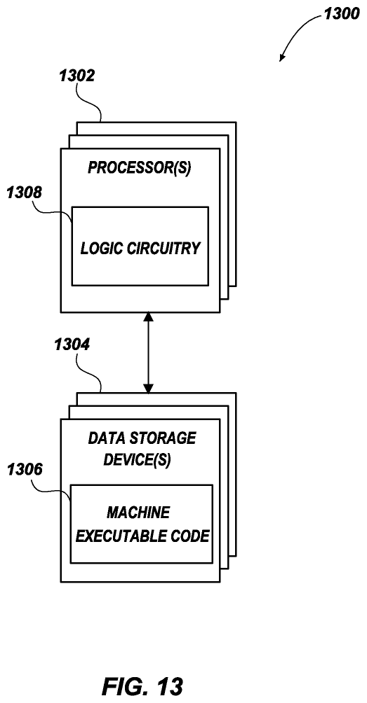

It will be appreciated by those of ordinary skill in the art that functional elements of examples disclosed herein (e.g., functions, operations, acts, processes, and/or methods) may be implemented in any suitable hardware, software, firmware, or combinations thereof. FIG. 13 illustrates non-limiting examples of implementations of functional elements disclosed herein. In one or more examples, some or all portions of the functional elements disclosed herein may be performed by hardware specially configured for carrying out the functional elements.

FIG. 13 is a block diagram of circuitry 1300 that, in one or more examples, may be used to implement various functions, operations, acts, processes, and/or methods disclosed herein. The circuitry 1300 includes one or more processors 1302 (sometimes referred to herein as “processors 1302”) operably coupled to one or more data storage devices (sometimes referred to herein as “storage 1304”). The storage 1304 includes machine executable code 1306 stored thereon and the processors 1302 include logic circuitry 1308. The machine executable code 1306 includes information describing functional elements that may be implemented by (e.g., performed by) the logic circuitry 1308. The logic circuitry 1308 is adapted to implement (e.g., perform) the functional elements described by the machine executable code 1306. The circuitry 1300, when executing the functional elements described by the machine executable code 1306, should be considered as special purpose hardware configured for carrying out functional elements disclosed herein. In one or more examples the processors 1302 may perform the functional elements described by the machine executable code 1306 sequentially, concurrently (e.g., on one or more different hardware platforms), or in one or more parallel process streams.

When implemented by logic circuitry 1308 of the processors 1302, the machine executable code 1306 is to adapt the processors 1302 to perform operations of examples disclosed herein. For example, the machine executable code 1306 may adapt the processors 1302 to perform at least a portion or a totality of the method 300 of FIG. 3, the method 400 of FIG. 4, the method 500 of FIG. 5, the method 600 of FIG. 6, the method 700 of FIG. 7, the method 800 of FIG. 8, the method 900 of FIG. 9, and/or the method 1000 of FIG. 10. As another example, the machine executable code 1306 may adapt the processors 1302 to perform at least a portion or a totality of the operations discussed for the apparatus of FIG. 2. As a specific, non-limiting example, the machine executable code 1306 may adapt the processors 1302 to provide a periodic signal including pulses to the first terminal where a duration of each of the pulses is greater than double a time of travel of the pulses along a length of a cable and detect a fault in the cable responsive to one or more reflections of the periodic signal received at the second terminal. As another specific, non-limiting example, the machine executable code 1306 may adapt the processors 1302 to provide a clock signal to a cable where a duration of a single clock cycle of the clock signal is greater than quadruple the time of travel of the clock along a length of the cable and detect a fault in the cable responsive to one or more reflections of the clock signal.

The processors 1302 may include a general purpose processor, a special purpose processor, a central processing unit (CPU), a microcontroller, a programmable logic controller (PLC), a digital signal processor (DSP), an Application Specific Integrated Circuit (ASIC), a Field-Programmable Gate Array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine executable code 1306 (e.g., software code, firmware code, hardware descriptions) related to examples of the present disclosure. It is noted that a general-purpose processor (may also be referred to herein as a host processor or simply a host) may be a microprocessor, but in the alternative, the processors 1302 may include any conventional processor, controller, microcontroller, or state machine. The processors 1302 may also be implemented as a combination of computing devices, such as a combination of a DSP and a microprocessor, a plurality of microprocessors, one or more microprocessors in conjunction with a DSP core, or any other such configuration.

In one or more examples, the storage 1304 includes volatile data storage (e.g., random-access memory (RAM)), non-volatile data storage (e.g., Flash memory, a hard disc drive, a solid state drive, erasable programmable read-only memory (EPROM), etc.). In one or more examples the processors 1302 and the storage 1304 may be implemented into a single device (e.g., a semiconductor device product, a system on chip (SOC), etc.). In one or more examples the processors 1302 and the storage 1304 may be implemented into separate devices.

In one or more examples, the machine executable code 1306 may include computer-readable instructions (e.g., software code, firmware code). By way of non-limiting example, the computer-readable instructions may be stored by the storage 1304, accessed directly by the processors 1302, and executed by the processors 1302 using at least the logic circuitry 1308. Also by way of non-limiting example, the computer-readable instructions may be stored on the storage 1304, transferred to a memory device (not shown) for execution, and executed by the processors 1302 using at least the logic circuitry 1308. Accordingly, in one or more examples the logic circuitry 1308 includes electrically configurable logic circuitry 1308.

In one or more examples, the machine executable code 1306 may describe hardware (e.g., circuitry) to be implemented in the logic circuitry 1308 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG™, SYSTEMVERILOG™ or very large scale integration (VLSI) hardware description language (VHDL™) may be used.

HDL descriptions may be converted into descriptions at any of numerous other levels of abstraction as desired. As a non-limiting example, a high-level description may be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuitry 1308 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in one or more examples the machine executable code 1306 may include an HDL, an RTL, a GL description, a mask level description, other hardware description, or any combination thereof.

In examples where the machine executable code 1306 includes a hardware description (at any level of abstraction), a system (not shown, but including the storage 1304) may implement the hardware description described by the machine executable code 1306. By way of non-limiting example, the processors 1302 may include a programmable logic device (e.g., an FPGA or a PLC) and the logic circuitry 1308 may be electrically controlled to implement circuitry corresponding to the hardware description into the logic circuitry 1308. Also by way of non-limiting example, the logic circuitry 1308 may include hard-wired logic manufactured by a manufacturing system (not shown, but including the storage 1304) according to the hardware description of the machine executable code 1306.

Regardless of whether the machine executable code 1306 includes computer-readable instructions or a hardware description, the logic circuitry 1308 is adapted to perform the functional elements described by the machine executable code 1306 when implementing the functional elements of the machine executable code 1306. It is noted that although a hardware description may not directly describe functional elements, a hardware description indirectly describes functional elements that the hardware elements described by the hardware description are capable of performing.

### CONCLUSION

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In one or more examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the present disclosure as hereinafter claimed along with their legal equivalents. In addition, features from one example may be combined with features of another example while still being encompassed within the scope of the present disclosure.

What is claimed is:

1. An apparatus, comprising:
a processing circuitry to:
provide a periodic signal including pulses to a first pair of terminals, a duration of each of the pulses greater than at least double a time of travel of the pulses along a predetermined allowed length of a cable; and
detect a fault in the cable responsive to a received signal at a second pair of terminals responsive to the periodic signal.

2. The apparatus of claim 1, wherein the cable is a network cable.

3. The apparatus of claim 2, wherein the network cable is a shared transmission medium of a wired local area network.

4. The apparatus of claim 1, wherein the processing circuitry is to detect an open circuit in the cable to detect the fault in the cable, responsive to:
a high magnitude pulse in the received signal for substantially an entirety of a duration of time for which a pulse of the periodic signal would transit the maximum allowed length of the cable, the high magnitude pulse having a higher magnitude than a magnitude of an echo pulse responsive to the periodic signal; or
a low magnitude pulse in the received signal following a leading edge of the one of the pulses of the periodic signal followed by a high magnitude pulse in the received signal within the entirety of the duration of time for which the pulse of the periodic signal would transit the maximum allowed length of the cable following the leading edge.

5. The apparatus of claim 1, wherein the processing circuitry is to detect a short circuit in the cable to detect the fault in the cable responsive to:
a low magnitude pulse in the received signal for substantially an entirety of a duration of time for which the pulse of the periodic signal would transit the maximum allowed length of the cable; or
a high magnitude pulse in the received signal following a leading edge of the periodic signal followed by a low magnitude pulse in the received signal within the entirety of the duration of time for which the pulse of the periodic signal would transit the maximum allowed length of the cable following the leading edge, the high magnitude pulse having a higher magnitude than a magnitude of an echo pulse responsive to the periodic signal.

6. The apparatus of claim 1, wherein the processing circuitry is to detect a location of the fault responsive to the received signal.

7. The apparatus of claim 1, wherein the processing circuitry is to detect a fault in the cable at a point of connection between the first pair of terminals and the cable responsive to:
a high magnitude pulse in the received signal for substantially the entirety of the duration of time for which the pulse of the periodic signal would transit the maximum allowed length of the cable, the high magnitude pulse having a higher magnitude than a magnitude of an echo pulse responsive to the periodic signal; or
a low magnitude pulse in the received signal for substantially an entirety of a duration of time for which the pulse of the periodic signal would transit the maximum allowed length of the cable following a leading edge of the pulse of the periodic signal.

8. The apparatus of claim 1, wherein the processing circuitry is to detect a fault in the cable at a distance greater than substantially zero meters from a point of connection between the cable and the first pair of terminals responsive to:
a low magnitude pulse in the received signal following a leading edge of a pulse of the periodic signal followed by a high magnitude pulse in the received signal within an entirety of a duration of time for which the pulse of the periodic signal would transit the maximum allowed length of the cable following the leading edge; or
a high magnitude pulse in the received signal following the leading edge of the pulse of the periodic signal followed by a low magnitude pulse in the received signal within the entirety of the duration of time for which the pulse of the periodic signal would transit the maximum allowed length of the cable following the leading edge, the high magnitude pulse having a higher magnitude than a magnitude of an echo pulse responsive to the periodic signal.

9. The apparatus of claim 8, wherein the processing circuitry is to detect a location of the fault in the cable responsive to:
a period of time beginning at the leading edge of the pulse of the periodic signal during which a low magnitude pulse is detected in the received signal; or
a period of time beginning at the leading edge of the pulse of the periodic signal during which the high magnitude pulse is detected in the received signal.

10. The apparatus of claim 1, wherein a duty cycle of the periodic signal is substantially 50%.

11. A method for cable fault detection, the method comprising:
providing a periodic signal including pulses to a cable, a duration of respective pulses, at least double a time of travel of the pulses along a maximum allowed length of the cable; and
detecting a fault in the cable responsive to a received signal, the received signal responsive to the periodic signal.

12. The method of claim 11, comprising detecting an open circuit in the cable responsive to:
detecting a high magnitude pulse in the received signal for substantially an entirety of a duration of time for which the periodic signal would transit the maximum allowed length of the cable, the high magnitude pulse having a higher magnitude than a magnitude of an echo pulse responsive to the periodic signal; or
detecting a low magnitude pulse in one or more reflections following a leading edge of the pulse in the periodic signal then a high magnitude pulse in the received signal within the duration of time for which the pulse of the periodic signal would transit the maximum allowed length of the cable following the leading edge.

13. The method of claim 11, comprising detecting a short circuit in the cable responsive to:
detecting a low magnitude pulse in one or more reflections following a leading edge of a pulse of the periodic signal in the one or more reflections; or
detecting a high magnitude pulse in the received signal following the leading edge of the periodic signal followed by a low magnitude pulse in the received signal within an entirety of a duration of time for which the pulse of the periodic signal would transit the maximum allowed length of the cable following the leading edge, the high magnitude pulse having a higher magnitude than a magnitude of an echo pulse responsive to the periodic signal.

14. The method of claim 11, further comprising detecting a location of the fault responsive to one or more reflections.

15. The method of claim 11, wherein the pulses corresponds to a first logic level of a clock signal.

16. The method of claim 15, wherein a duty cycle of the clock signal is substantially 50%.

17. An apparatus comprising:
a signal generator to provide, to a cable, a clock signal, a duration of a single clock cycle of the clock signal greater than quadruple a time of travel of a pulse of the clock signal along a maximum allowed length of the cable; and
a processing circuitry to detect a fault in the cable responsive to a received signal, the received signal received from the cable responsive to the clock signal.

18. The apparatus of claim 17, wherein the processing circuitry to detect an open circuit in the cable responsive to:
a high magnitude pulse in the received signal for substantially an entirety of a duration of time for which the clock signal would transit the maximum allowed length of the cable; or
a low magnitude pulse following a leading edge of the clock signal in the received signal followed by a high magnitude pulse in one or more reflections within the entirety of the duration of time for which the pulse of the clock signal would transit the maximum allowed length of the cable following the leading edge, the high magnitude pulse having a higher magnitude than a magnitude of an echo pulse responsive to the clock signal.

19. The apparatus of claim 18, wherein the processing circuitry to detect a short circuit in the cable responsive to:
a low magnitude pulse in the received signal for substantially an entirety of a duration of time for which the clock signal would transit the maximum allowed length of the cable; or
a high magnitude pulse in the received signal following a leading edge of the pulse followed by a low magnitude pulse in the received signal within the entirety of the duration of time for which the pulse of the clock signal would transit the maximum allowed length of the cable following the leading edge, the high magnitude pulse having a higher magnitude than a magnitude of an echo pulse responsive to the clock signal.
